(19) United States
(12) Patent Application Publication
(10) Pub. No.: US 2017/0062438 A1
(43) Pub. Date: Mar. 2, 2017

(54) ELECTRICAL GATE-TO-SOURCE/DRAIN CONNECTION

(71) Applicant: GLOBALFOUNDRIES Inc., Grand Cayman (KY)

(72) Inventors: Hans-Peter Moll, Dresden (DE); Peter Baars, Dresden (DE)

(21) Appl. No.: 15/146,979

(22) Filed: May 5, 2016

Related U.S. Application Data
(60) Provisional application No. 62/211,100, filed on Aug. 28, 2015.

(51) Int. Cl. H01L 27/11; H01L 29/417; H01L 29/49; H01L 29/45; H01L 29/06; H01L 27/12; H01L 29/08; H01L 29/66

(52) U.S. Cl. CPC H01L 27/1104; H01L 29/0847; H01L 29/41783; H01L 29/665; H01L 29/66515; H01L 29/45; H01L 29/0649; H01L 27/1203; H01L 29/4966; H01L 29/4958

(57) ABSTRACT

A method of manufacturing a semiconductor device is provided including forming a gate electrode layer over a semiconductor substrate, forming a sidewall spacer at a sidewall of the gate electrode layer, forming a raised source/drain region over the semiconductor substrate and adjacent to the sidewall spacer, removing a portion of the sidewall spacer, thereby exposing a portion of the sidewall of the gate electrode layer, and forming an electrically conductive layer electrically connecting the exposed portion of the sidewall of the gate electrode layer and the source/drain region.

### BACKGROUND OF THE INVENTION

1. Field of the Invention

Generally, the present disclosure relates to the field of manufacturing of integrated circuits and semiconductor devices, and, more particularly, to the formation of electrical gate to source/drain connections of transistor devices.

2. Description of the Related Art

The fabrication of advanced integrated circuits, such as CPUs, storage devices, ASICs (application specific integrated circuits) and the like, requires the formation of a large number of circuit elements on a given chip area according to a specified circuit layout. In a wide variety of electronic circuits, field effect transistors represent one important type of circuit element that substantially determines performance of the integrated circuits. Generally, a plurality of process technologies are currently practiced for forming field effect transistors, wherein, for many types of complex circuitry, MOS technology is currently one of the most promising approaches due to the superior characteristics in view of operating speed and/or power consumption and/or cost efficiency. During the fabrication of complex integrated circuits using, for instance, MOS technology, millions of transistors, e.g., N-channel transistors and/or P-channel transistors, are formed on a substrate including a crystalline semiconductor layer. Miniaturization and increase of circuit densities represent ongoing demands.

A field effect transistor, irrespective of whether an N-channel transistor or a P-channel transistor is considered, typically comprises so-called PN junctions that are formed by an interface of highly doped regions, referred to as drain and source regions, with a slightly doped or non-doped region, such as a channel region, disposed between the highly doped regions. In a field effect transistor, the conductivity of the channel region, i.e., the drive current capability of the conductive channel, is controlled by agate electrode formed adjacent to the channel region and separated therefrom by a thin insulating layer. The conductivity of the channel region, upon formation of a conductive channel due to the application of an appropriate control voltage to the gate electrode, depends on, among other things, the dopant concentration, the mobility of the charge carriers and, for a given extension of the channel region in the transistor width direction, on the distance between the source and drain regions, which is also referred to as channel length.

A major issue encountered when increasing the performance of semiconductor devices and reducing the power consumption of semiconductor devices is given by contact and/or serial resistances (series resistors), especially in CMOS devices. In technologies concerning low power semiconductor devices, a possible approach to reduce contact resistances is given by a so-called raised source/drain approach. According to this approach, raised source regions and raised drain regions are formed adjacent a gate el ct ode by selectively epitaxially growing a semiconductor material layer over a semiconductor substrate, for example. Usually, a subsequent formation of silicided regions in the raised source and drain regions is performed to improve contacting by reducing the contact resistance.

Particularly in the context of SRAM devices, electrical connections between gates and source/drain regions have to be formed. In the art, it is known to provide such electrical connections by means of rectangular contacts (so-called Carecs). FIGS. 1a (top view) and 1b (cross-sectional view) illustrate a semiconductor device comprising a Carec 1 of the art. As can be seen in FIG. 1a, the Carec is L-shaped when viewed from above. The semiconductor device is formed on a SOI substrate comprising a buried oxide layer 2 and a semiconductor layer 3 formed on the buried oxide layer 2. Two transistor devices comprising gate dielectrics 4, gate electrodes 5, sidewall spacers 6 and raised source/drain regions 7 are shown in FIG. 1b. As can be seen in FIG. 1a, in addition to the Carec 1, regular contacts 8 are formed for contacting the source/drain regions 7.

The formation of Carecs as the one shown in FIGS. 1a and 1b represents a critical issue in the overall contact patterning. For example, the critical dimension (CD) control of the long axes of Carecs is more than two times worse than the one of regular contacts (CAs) used for contacting source/drain regions through interlayer dielectrics. Due to the relatively poor control of the lengths of Carecs, there is a significant risk for short contacting of Carecs with VDD nodes. This problem is already a limiting factor for contact patterning in the context of 28 nm technology. In the context of continuous substrate (RX) manufacturing, an L-shaped Carec is usually formed over a continuous RX region in logic parts of semiconductor devices. According to the continuous RX approach, the continuous RX region denotes an active silicon layer generally surrounded by shallow trench isolations regions but having a part that is not isolated by the shallow trench isolation. However, due to the poor length control of the L-shaped Carec, it is necessary to provide for some landing pad, for example, by widening a portion of the gate polysilicon layer of the middle gate as illustrated in FIG. 1a, in order to avoid shorting to adjacent raised source/drain regions. However, the locally varying sizes of the gate polysilicon layers negatively affect the control of the patterning of the same and the CD control, in general.

In view of the situation described above, the present disclosure provides techniques for the formation of gate to source/drain connections that avoid the above-mentioned problems.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally the subject matter disclosed herein relates to the formation of semiconductor devices, for example, transistor devices, and more particularly MOSFETs, and even more particularly SRAM devices.

A method of manufacturing a semiconductor device is provided including the formation of a transistor device and/or an SRAM device (cell). The method includes the steps of forming a gate electrode layer over a semiconductor substrate (for example, an SOI semiconductor substrate, in particular, an FDSOI semiconductor substrate having a semiconductor layer providing a channel region of a transistor device), forming a sidewall spacer at a sidewall of the gate electrode layer, forming a raised source/drain region (source or drain) over the semiconductor substrate and adjacent to the sidewall spacer, removing a portion of the sidewall spacer, thereby exposing a portion of the sidewall of the gate electrode layer, and forming an electrically conductive layer electrically connecting the exposed portion of the sidewall of the gate electrode layer and the source/drain region. The electrically conductive layer may be a layer comprising a metal material, in particular, a metal silicide material, and may be formed during the process of silicidation of the source/drain region and the gate electrode layer.

According to another example, a method of manufacturing a semiconductor device is provided including forming a gate electrode layer over a semiconductor substrate, forming a sidewall spacer at a sidewall of the gate electrode layer such that it covers a first portion of the sidewall and exposes a second portion of the sidewall, forming a raised source/drain region over the semiconductor substrate and adjacent to the sidewall spacer, and performing a silicidation process to obtain a silicided portion of the gate electrode layer, a silicided portion of the source/drain region and a silicided layer connecting the silicided portion of the gate electrode layer and silicided portion of the source/drain region. The silicided portions and the silicided layer may be formed continuously.

Furthermore, a semiconductor device is provided including a semiconductor substrate, a gate electrode layer formed over the semiconductor substrate, a sidewall spacer formed at a sidewall of the gate electrode layer covering only a first portion and exposing a second portion of the sidewall, a raised source/drain region adjacent to the sidewall spacer and formed over the semiconductor substrate, and an electrically conductive layer continuously formed partly on the exposed second portion of the sidewall of the gate electrode and the raised source/drain region. The electrically conductive layer may comprise a metal or metal silicide material and electrically connects the gate electrode layer and the source/drain region.

### BRIEF DESCRIPTION OF THE DRAWINGS

The disclosure may be understood by reference to the following description taken in conjunction with the accompanying drawings, in which like reference numerals identify like elements, and in which:

FIGS. 1a and 1b show a semiconductor device comprising an L-shaped Carec according to an example of the art;

FIGS. 2a-2c illustrate a process flow for manufacturing a semiconductor device according to an example of the present disclosure comprising a partial removal of a sidewall spacer formed on a sidewall of a transistor gate and formation of a bridge between the gate and a raised source/drain region; and

FIGS. 3a-3f Illustrate an exemplary process flow for manufacturing the semiconductor device illustrated in FIG. 2a.

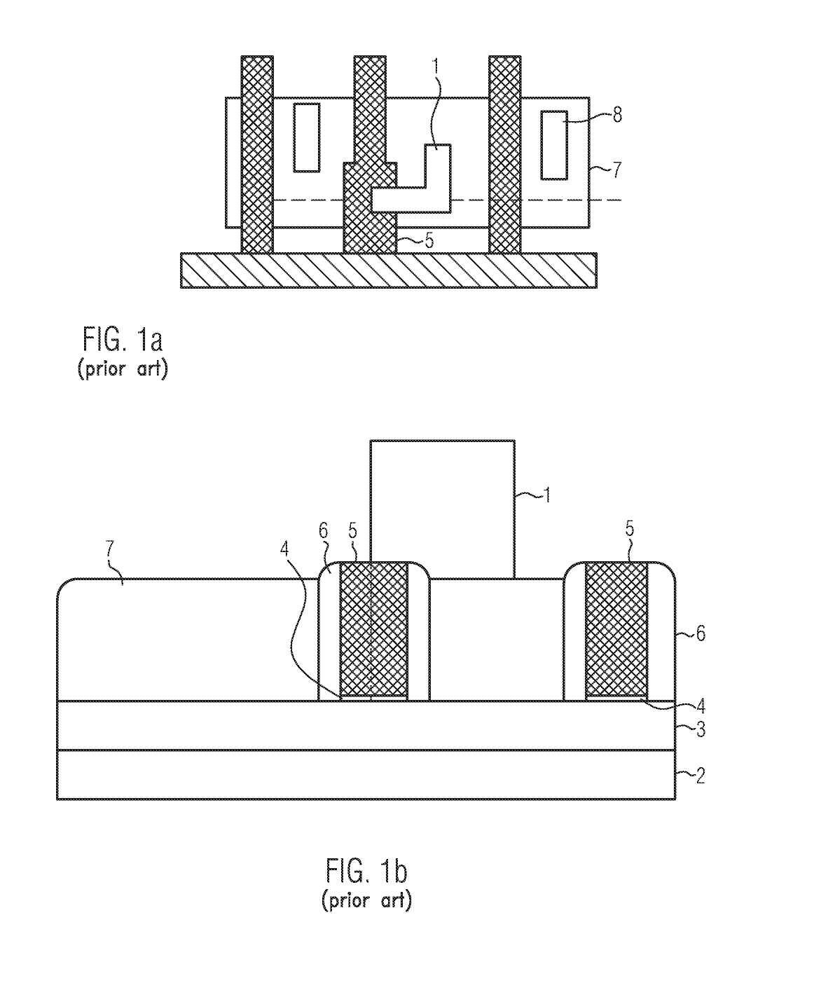

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The following embodiments are described in sufficient detail to enable those skilled in the art to make use of the disclosure. It is to be understood that other embodiments would be evident, based on the present disclosure, and that system, structure, process or mechanical changes may be made without departing from the scope of the present disclosure. In the following description, numeral-specific details are given to provide a thorough understanding of the disclosure. However, it would be apparent that the embodiments of the disclosure may be practiced without the specific details. In order to avoid obscuring the present disclosure, some well-known circuits, system configurations, structure configurations and process steps are not disclosed in detail.

The present disclosure will now be described with reference to the attached figures. Various structures, systems and devices are schematically depicted in the drawings for purposes of explanation only and so as to not obscure the present disclosure with details which are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary or customary meaning as understood by those skilled in the art, is intended to be implied by consistent usage of the term or phrase herein. To the extent that a term or phrase is intended to have a special meaning, i.e., a meaning other than that understood by skilled artisans, such a special definition shall be expressively set forth in the specification in a definitional manner that directly and unequivocally provides the special definition for the term or phrase.

As will be readily apparent to those skilled in the art upon a complete reading of the present application, the present methods are applicable to a variety of technologies, e.g., NMOS, PMOS, CMOS, etc., and is readily applicable to a variety of devices, including, but not limited to, logic devices, SRAM devices, etc. Generally, manufacturing techniques and semiconductor devices in which N-channel transistors and/or P-channel transistors may be formed are described herein. The manufacturing techniques may be integrated in CMOS manufacturing processes. The techniques and technologies described herein can be utilized to fabricate MOS integrated circuit devices, including NMOS integrated circuit devices, PMOS integrated circuit devices, and CMOS integrated circuit devices. In particular, the process steps described herein are utilized in conjunction with any semiconductor device fabrication process that forms gate structures for integrated circuits, including both planar and non-planar integrated circuits. Although the term “MOS” properly refers to a device having a metal gate electrode and an oxide gate insulator, that term is used throughout to refer to any semiconductor device that includes a conductive gate electrode (whether metal or other conductive material) that is positioned over a gate insulator (whether oxide or other insulator) which, in turn, is positioned over a semiconductor substrate.

In principle, there are two well-known processing methods for forming a planar or 3D transistor with a high-k/metal gate (HK/MG) structure: (1) the so-called “gate last” or “replacement gate” technique; and (2) the so-called “gate first” technique. In general, using the “gate first” technique involves forming a stack of layers of material across the substrate, wherein the stack of materials includes a high-k gate insulation layer (i.e., a layer with a dielectric constant k higher than the one of SiO₂), one or more metal layers, a layer of polysilicon and a protective cap layer, for example, silicon nitride. Thereafter, one or more etching processes are performed to pattern the stack of materials to thereby define the basic gate structures for the transistor devices. In the replacement gate technique, a so-called “dummy” or sacrificial gate structure is initially formed and remains in place as many process operations are performed to form the device, e.g., the formation of doped source/drain regions, performing an anneal process to repair damage to the substrate caused by the ion implantation processes and to activate the implanted dopant materials. At some stage of the process flow, the sacrificial gate structure is removed to define a gate cavity where the final HK/MG gate structure for the device is formed. The herein disclosed techniques can be applied to the gate first approach.

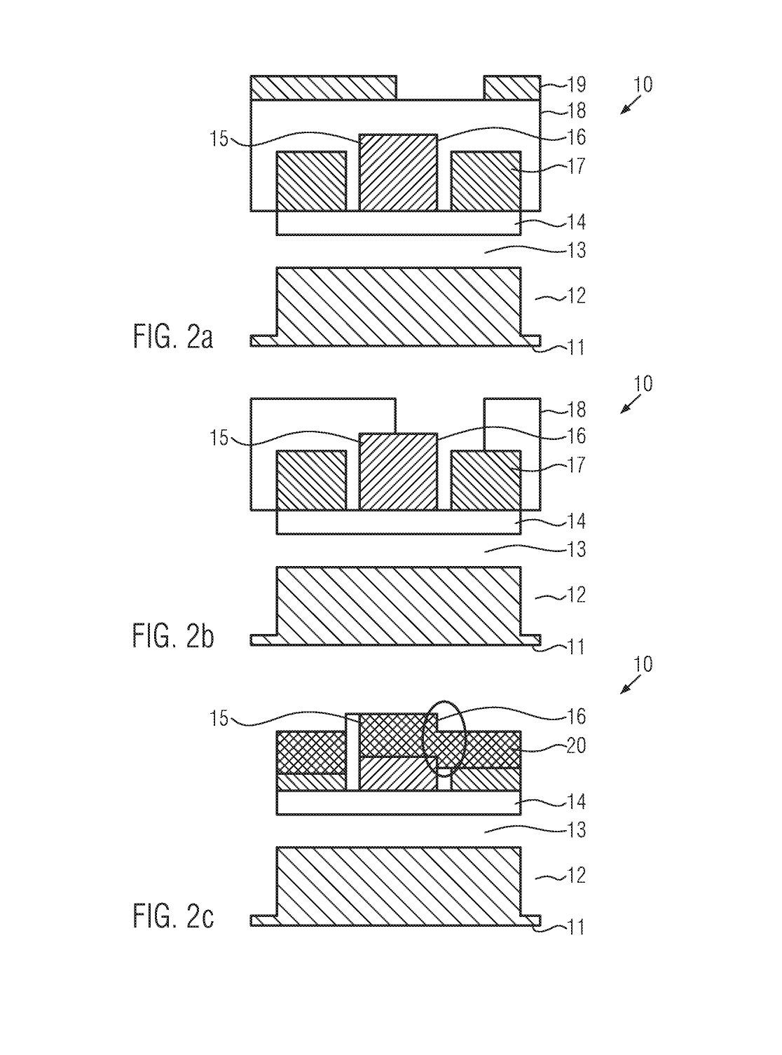

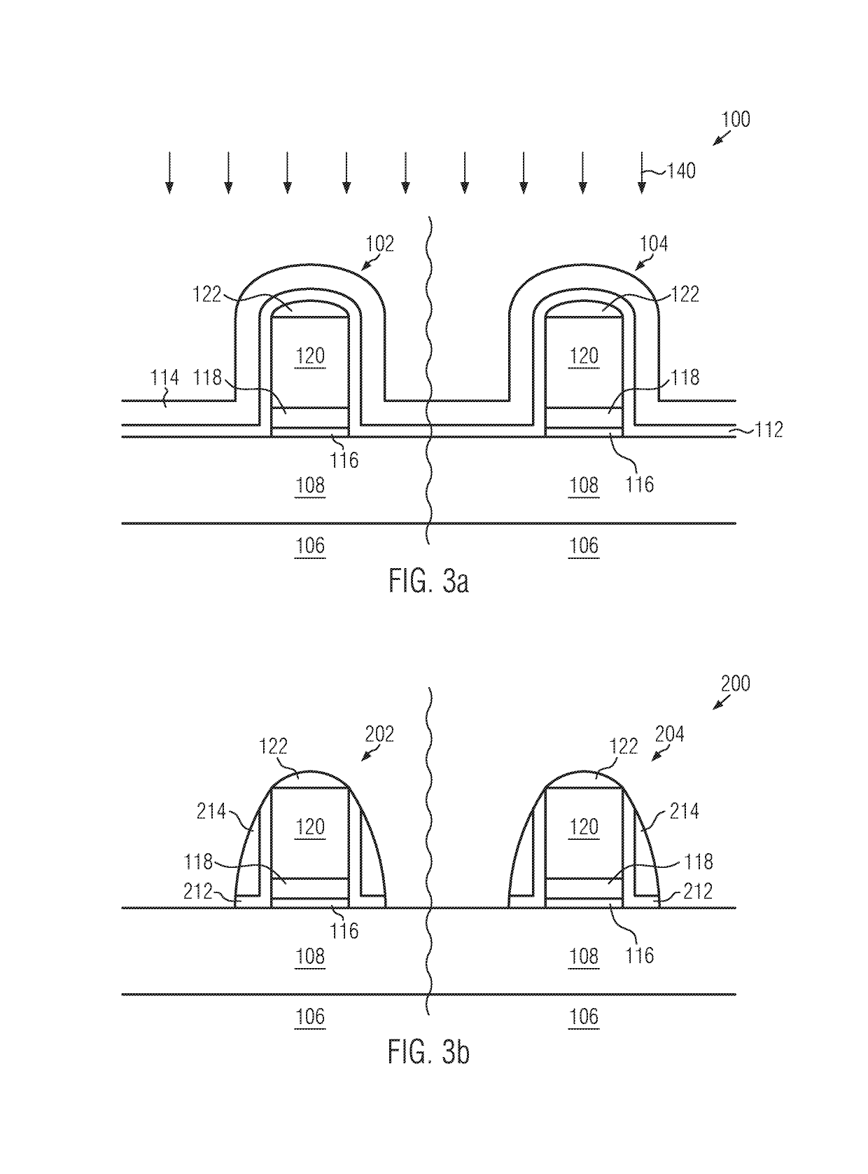

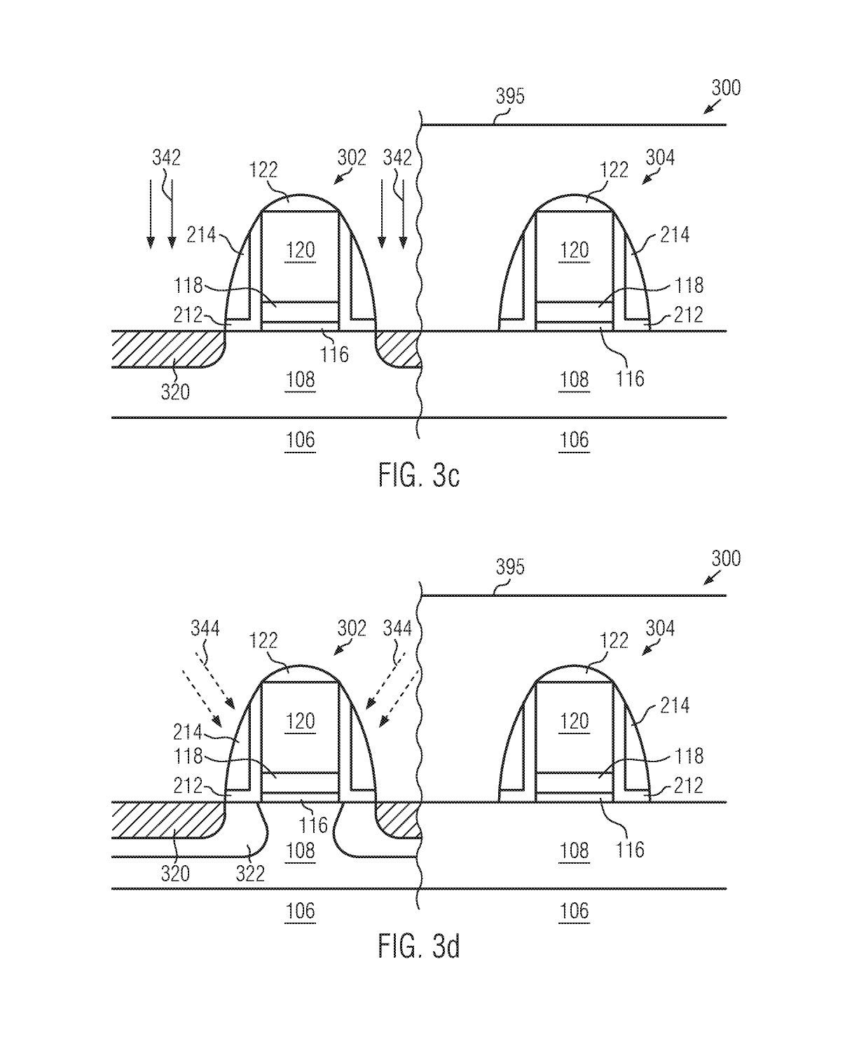

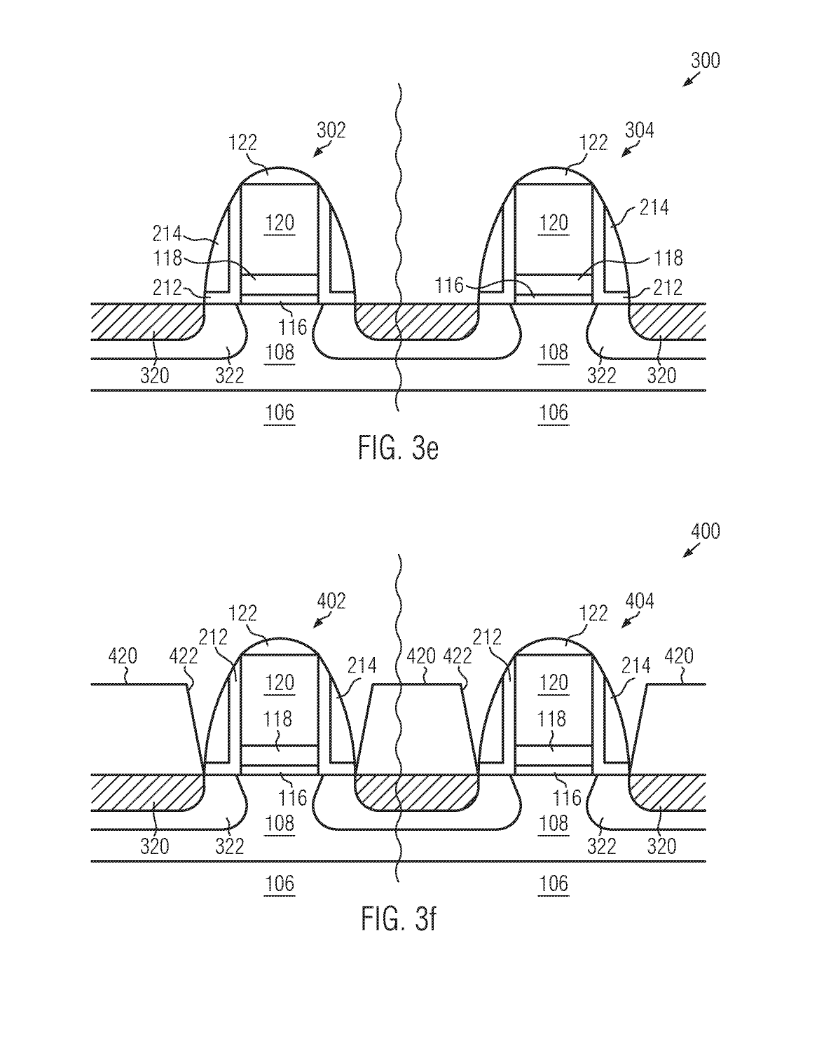

The present disclosure provides a method of manufacturing a semiconductor device including electrical connecting gates and source/drain regions of FETs. The FETs may be comprised in an SRAM device. An example of this method according to the present disclosure is illustrated in FIGS. 2a-2c and 3a-3f FIG. 2a illustrates a semiconductor device 10 comprising a transistor device formed on an SOI semiconductor substrate, for example, a fully depleted SOI (FDSOI) semiconductor substrate. The semiconductor device 10 comprises a bulk semiconductor substrate 11 wherein insulation regions 12, for example, shallow trench insulations, are formed. The bulk semiconductor substrate 11 can be a silicon substrate, in particular, a single crystal silicon substrate. Other materials can be used to form the semiconductor substrate such as, for example, germanium, silicon germanium, gallium phosphate, gallium arsenide, etc. The insulation regions 12 define an active region and electrically isolate the transistor device from other active or passive devices formed on the same SOI substrate. The insulation regions may be parts of a contiguous trench isolation structure and may be formed by etching the bulk semiconductor substrate 11 and filling the formed trenches with some dielectric material, for example, silicon oxide. An insulation/buried oxide layer 13 is formed on the bulk semiconductor substrate 11. The buried oxide layer 13 may include a dielectric material, such as silicon dioxide, and may be an ultra-thin buried oxide (UT-BOX) having a thickness in a range from about 10-20 nm,

A semiconductor layer 14 is formed on the buried oxide layer 13. The semiconductor layer 14 provides the channel region of the transistor device and may be comprised of any appropriate semiconductor material, such as silicon, silicon/germanium, silicon/carbon, other II-VI or III-V semiconductor compounds and the like. The semiconductor layer 14 may have a thickness suitable for forming a fully depleted field effect transistor, for example, a thickness in a range from about 5-8 nm. A gate electrode layer 15 is formed over the semiconductor layer 14. The gate electrode layer 15 may be formed on or over a gate dielectric layer (not shown in FIGS. 2a-2c). The gate electrode layer 15 may comprise a metal gate. The material of the metal gate may depend on whether the transistor device to be formed is a P-channel transistor or an N-channel transistor. In embodiments wherein the transistor device is an N-channel transistor, the metal may include La, LaN or TiN. In embodiments wherein the transistor device is a P-channel transistor, the metal may include Al, AlN or TiN. The metal gate may include a work function adjusting material, for example, TiN. In particular, the metal may comprise a work function adjusting material that comprises an appropriate transition metal nitride, for example, those from Groups 4-6 in the Periodic Table, including, for example, titanium nitride (TiN), tantalum nitride (TaN), titanium aluminum nitride (TiAlN), tantalum aluminum nitride (TaAlN), niobium nitride (NbN), vanadium nitride (VN), tungsten nitride (WN), and the like with a thickness of about 1-60 nm. Moreover, the effective work function of the metal gate can be adjusted by added impurities, for example, Al, C or F. Moreover, the gate electrode layer 15 may comprise a polysilicon gate at the top of the metal gate.

Sidewall spacers 16, for example, comprising silicon dioxide and/or silicon nitride, are formed at sidewalls of the gate electrode layer 15. The sidewall spacers 16 may include a plurality of spacer layers. Adjacent to the sidewall spacers 16, raised source/drain regions 17 are formed. Formation of the raised source/drain regions 17 may include epitaxially growing a semiconductor material over the semiconductor layer 14 and appropriate doping of the same after or during the epitaxial growth.

An exemplary process sequence of forming the semiconductor device 10 described so far is illustrated in FIGS. 3a-3f. FIG. 3a shows a schematic cross-sectional view of a semiconductor device 100 at an early stage of a process for forming semiconductor devices according to an embodiment of the present disclosure. The semiconductor device 100 comprises a buried oxide layer 106 formed on a bulk substrate (not shown). A layer of a semiconducting material 108 may be formed on the buried oxide layer 106. Shallow trench isolations (STI) (not shown) may electrically isolate individual transistor devices from each other. The semiconductor device 100 as depicted in FIG. 3a may comprise an N-channel transistor 102 and a P-channel transistor 104. A gate electrode structure of N-channel transistor 102 and/or of P-channel transistor 104 may comprise a high-k dielectric layer 116 with a dielectric constant k of above 4, a work function adjusting layer 118, a gate electrode layer 120, for example, comprising a polysilicon layer and/or a metal layer, and a cap layer 122. The cap layer 122 may comprise a plurality of layers and may particularly comprise a silicon oxide material and may have a thickness in a range from 10-100 nm or in a range from 20-50 nm or in a range from 25-45 nm, The high-k material layer 116 may comprise a transitional metal oxide, such as at least one of hafnium oxide, hafnium dioxide and hafnium silicon-oxynitride. The high-k material layer 116 may be directly formed on the semiconductor layer 108. The work function adjusting layer 118 may comprise titanium nitride (TiN) or any other appropriate work function adjusting metal or metal oxide that is known in the art.

On the side of the P-channel transistor 104, semiconductor layer 108 may have a selective silicon/germanium channel. The channel may have a thickness of less than 20 nm and more than 1 nm or a thickness of less than 10 nm and more than 5 nm. The selective silicon/germanium channel may be provided to adjust the threshold voltage of the P-channel transistor 104 in order to match the threshold voltage of the P-channel transistor 104 with the threshold voltage of the N-channel transistor 102.

A first insulating layer 112 and a second insulating layer 114 may be formed over he gate electrode structure and the substrate. The first and second insulating layers 112, 114 may be formed by, for instance, epitaxially growing or depositing respective layers. The first and/or the second insulating layers 112, 114 may be substantially uniformly formed over the semiconductor layer 108 and/or at least one gate electrode structure. The first insulating layer 112 may be comprised of silicon nitride (SiN). The first insulating layer 112 may have a thickness of substantially less than 10 nm or may have a thickness of substantially less than 5 nm or may have a thickness of substantially less than 1 nm or may substantially be a monolayer having a thickness of less than 1 nm. The second insulating layer 114 may comprise silicon dioxide (SiO₂) and may have a thickness which is substantially greater than the thickness of the first insulating layer 112. The second insulating layer 114 may have a thickness which is substantially greater than 1 nm or which is substantially greater than 5 nm or which is substantially greater than 10 nm.

As indicated by the arrows, etching 140 may be performed in order to form sidewall spacers, thereby resulting in the semiconductor device 200 shown in FIG. 3b. The etching may comprise one etching step or may alternatively comprise two or more etching steps.

As depicted in FIG. 3b, a first spacer structure is formed laterally disposed with regard to a gate electrode structure of an N-channel transistor 202, and a first spacer structure is formed laterally disposed with regard to agate electrode structure of a P-channel transistor 204. The first spacer structure has a first spacer liner 212 and a first sidewall spacer 214, thus forming a sidewall spacer structure. The first spacer liner 212 may have a substantially L-type shape. The first spacer liner 212 may cover at least a portion of a sidewall surface of the gat electrode structure of N-channel transistor 202 and/or P-channel transistor 204. The first spacer liner 212 may additionally or alternatively cover a portion of the semiconductor layer 108 in a region adjacent the gate electrode structure of N-channel transistor 202 and/or of P-channel transistor 204. The first sidewall spacer 214 may be disposed over the first spacer liner 212. The first sidewall spacer 214 may be disposed so as to at least partially cover the first space liner 212. By the spacer structures, the gate electrode structure and, in particular, the high-k dielectric layer 116 may be reliably and stably protected during etching and cleaning steps which are to be subsequently performed.

FIG. 3c shows a semiconductor device 300 having a first spacer structure 214, 212 disposed laterally to a gate electrode structure of an N-channel transistor 302 and/or a P-channel transistor 304. As schematically depicted in FIG. 3c, a mask or hard mask 395 may be disposed over the P-channel transistor 304 in order to protect the P-channel transistor 304 from subsequent processing steps. The mask or hard mask 395 may be based on a photoresist and may be formed in accordance with corresponding deposition steps. Due to the patterned mask or hard mask 395, the N-channel transistor 302 is exposed to processing steps at this stage and the P-channel transistor 304 is not exposed to the processing steps at this stage.

Furthermore, FIG. 3c schematically depicts an implantation step 342 during which source and drain extension regions 320 may be formed in the semiconductor layer 108. The first spacer structure 212, 214 may represent a first masking pattern for the implantation of source/drain extension regions 320. The source/drain extension regions 320 may be aligned with regard to the first spacer structure 212, 214. It is understood that source/drain extension regions 320 may possibly extend under the first spacer structure 212, 214. The first spacer structure 212, 214 may set the distance of the source/drain extension regions 320. The cap layer 122 protects the gate electrode structure of the N-channel transistor 302 from being affected by implantation step 342.

The N-channel transistor 302 may be exposed to a subsequent halo implantation step 344 by which halo regions 322 may be formed in the semiconductor layer 108 at the side of the N-channel transistor 302, as illustrated in FIG. 3d. The halo implantation step 344 may be performed under an inclined angle with regard to the exposed surface of the semiconductor layer 108, i.e., an angle under which the halo implantation step is performed with regard to the exposed surface of the semiconductor layer 108 is substantially different from a direction parallel to a normal direction of the exposed surface of the semiconductor layer 108. Subsequent to the aforementioned implantation steps, the mask or hard mask 395 may be removed such that the P-channel transistor 304 may be exposed to corresponding implantation steps for accordingly forming source/drain extension regions and/or halo regions in the P-channel transistor 304. After applying source/drain extension region implantation steps and halo implantation steps to the N-channel transistor 302 and the P-channel transistor 304, source/drain extension regions 320 and halo regions 322 may be formed in the N-channel transistors 302 and the P-channel transistors 304, as depicted in FIG. 3e.

It is expressly noted that, in the context of FDSOI applications, source/drain extension regions and halo regions may not be provided in the above-described examples.

Although not shown in FIG. 3e, it is possible to embed stressor regions (not shown) into extended source/drain regions 320 of the N-channel transistor 302 and/or the P-channel transistor 304 for imparting stress on the channel region of the N-channel transistor 302 and/or the P-channel transistor 304 disposed under the gate electrode structure of the N-channel transistor 302 and/or the P-channel transistor 304. By imparting stress on channel regions, the mobility of charge carriers in the channel region can be improved. For example, a silicon/germanium region (not shown) forming a lattice mismatched region adjacent the channel of the P-channel transistor 304 may be embedded in the semiconductor layer 108 at the P-channel transistor 304 to a depth greater than the depth of the selective silicon/germanium channel of the semiconductor device 304.

FIG. 3f depicts a semiconductor device 400 in a process step where a semiconductor layer 420 is formed over an exposed surface of the semiconductor layer 108 at both sides of the gate electrodes. The semiconductor layer 420 may be formed over the source/drain extension regions 320. The semiconductor layer 420 may comprise silicon, in particular, undoped silicon. The formation of the semiconductor layer 420 may be performed by epitaxially growing or selectively epitaxially growing or by depositing a semiconductor material which is to form the semiconductor layer 420 over exposed surfaces of the semiconductor layer 108 of the N-channel transistor 402 and/or the P-channel transistor 404. The thickness of the semiconductor layer 420 may be in a range between approximately 20-40 nm. The person with ordinary skills in the art will appreciate that at least the first spacer structure may be used as a first masking pattern the depositing the semiconductor layer 420 while reliably encapsulating and protecting the gate electrode structure of the N-channel transistor 402 and the P-channel transistor 404 and maintaining the first spacer structure 212, 214 and the cap layer 122.

The semiconductor layer 420 may be formed over at least a portion of the exposed surface of the semiconductor layer 108 substrate at both sides of the gate electrode, The semiconductor layer has a beveled layer portion 422 which is beveled (from top to bottom) towards the gate electrode structure of the N-channel transistor 402 and the P-channel transistor 404 with regard to the surface of the semiconductor layer 108. Whereas the beveled layer portion 422 of the semiconductor layer 420 reduces possible parasitic capacitances which may arise due to portions of raised source/drain regions which are disposed adjacent gate electrode structures, it may alternatively be preferred to form a non-beveled semiconductor layer 420. For forming the beveled layer portion 422, an epitaxy technique may be performed which makes use of the effect that the speed of epitaxial growth depends on the orientation of the crystal surface on which material is to be grown. After a complete reading of the present application, a person skilled in the art will appreciate that growth of silicon on a (111) surface may be substantially suppressed. However, this does not pose any limitation on the present disclosure, and other techniques may be considered for forming beveled layer portions 422. The semiconductor layer 420 can be properly doped during the epitaxial growth or afterwards in order to form raised source/drain regions. The height of the semiconductor layer 420 and thereby the raised source/drain regions can properly be selected. For example, the height might be chosen similar to the one of the gate electrode layers 120 (compare the heights of the gate electrode layer 15 and the source/drain regions 17 of FIG. 2a). After formation of the raised source/drain regions from the semiconductor layer 420, the cap layer 122 can be removed.

The semiconductor device 100 shown in FIG. 2a may be formed according to the process sequence described with reference to FIGS. 3a-3f. It may be formed similar to the P-channel transistor 204, 304, 404 or similar to the N-channel transistor 202, 302, 402 shown in FIGS. 3b-3f. Moreover, in the processing stage shown in FIG. 2a, after removal of the cap layer 122 covering the gate electrode layer 120 in the stage shown in FIG. 3f, a mask layer 18 is deposited. For example, the mask layer 18 is an organic planarizing hard mask. An etching mask 19, for example, a resist mask, in particular, an SiON mask, is formed on the mask layer 18 and patterned to expose a portion of the mask layer covering a region where an electrical connection between the gate electrode layer 15 and the source/drain region 17 is to be formed.

As illustrated in FIG. 2b, the mask layer 18 is selectively etched by means of the etching mask 19 in order to expose a region where an electrical connection between the gate electrode layer 15 and the source/drain region 17 is to be formed. The patterned mask layer 18 can be used to partially remove the sidewall spacer 16. Removal of the part of the sidewall spacer 16 can be achieved by reactive ion etching, for example.

A silicide layer 20, for example, comprised of NiSi, may be formed in the raised source/drain regions 17 as well the gate electrode layer 15 after removal of the patterned mask layer 18, as illustrated in FIG. 2c. For this purpose, a metal layer may be deposited over the structure resulting after removal of the mask layer 18 and an anneal process may be performed for initiating a chemical reaction between the metal of the metal layer and the semiconductor material of the raised source/drain regions 17 and the gate electrode layer 15.

The silicidation process is known to improve electrical contact resistance of the raised source/drain regions 17 and the gate electrode layer 15, However, as disclosed herein, the formation of the silicide layer 20 additionally results in contacting the gate electrode layer 15 and the source/drain region 17 as illustrated by the oval contour shown in FIG. 2c. Silicidation of the raised source/drain regions 17 and the gate electrode layer 15 and formation of the silicided bridge connecting the raised source/drain regions 17 and the gate electrode layer 15 can particularly be performed in one single processing step. It is further noted that such a bridge can be formed on both sides of the gate electrode 15, thereby connecting the gate electrode 15 to both a source and a drain electrode.

As a result, a method of manufacturing a semiconductor device is provided including electrically connecting a gate and a source/drain region of a FET without the need for the formation of a Carec. Printing of regular contacts only is needed rather than Carec printing. In particular, the overall contacting process may be performed by using one single contacting mask only. Contrary, in the art, at least two contacting masks, namely, one for regular contacts and one for Carecs, were needed. In the context of continuous RX manufacturing processes, no upsizing of the RX is needed that conventionally was necessary in order to provide for landing pads of the Carecs. The disclosed techniques can be used in the formation of logic parts of semiconductor devices and SRAMS, for example.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

What is claimed:

1. A method of manufacturing a semiconductor device, comprising:
forming a gate electrode layer over a semiconductor substrate;
forming a sidewall spacer at a sidewall of said gate electrode layer;
forming a raised source/drain region over said semiconductor substrate and adjacent to said sidewall spacer;
removing a portion of said sidewall spacer, thereby exposing a portion of said sidewall of said gate electrode layer; and
forming an electrically conductive layer electrically connecting said exposed portion of said sidewall of said gate electrode layer and said source/drain region.

2. The method of claim 1, further comprising forming a patterned mask layer over said gate electrode layer and said raised source/drain regions, said patterned mask layer exposing said portion of said sidewall spacer.

3. The method of claim 1, wherein forming said electrically conductive layer comprises performing silicidation of said gate electrode layer and said raised source/drain region.

4. The method of claim 1, wherein forming said electrically conductive layer comprises performing silicidation of said gate electrode layer and said raised source/drain region and further comprising forming a metal layer over said gate electrode layer including said exposed portion of said sidewall of said gate electrode layer, said raised source/drain regions and a remaining portion of said sidewall spacer and performing an anneal treatment of said metal layer in order to form a metal silicide layer.

5. The method of claim 1, wherein said electrically conductive layer is partly formed in said gate electrode layer and said source/drain region.

6. The method of claim 1, further comprising providing said semiconductor substrate by forming a buried oxide layer on a semiconductor bulk substrate and forming a semiconductor layer on said buried oxide layer.

7. The method of claim 1, further comprising forming an additional sidewall spacer at another sidewall of said gate electrode, forming another source/drain region and removing a portion of said other sidewall spacer, thereby exposing a portion of said other sidewall of said gate electrode layer and wherein said electrically conductive layer is formed to electrically contact said other source/drain region and said exposed portion of said other sidewall of said gate electrode layer.

8. A semiconductor device, comprising:
a semiconductor substrate;
a gate electrode layer formed over said semiconductor substrate;
a sidewall spacer formed at a sidewall of said gate electrode layer covering only a first portion and exposing a second portion of said sidewall;
a raised source/drain region adjacent to said sidewall spacer and formed over said semiconductor substrate; and
an electrically conductive layer continuously formed partly on said exposed second portion of said sidewall of said gate electrode and said raised source/drain region.

9. The semiconductor device of claim 8, wherein said electrically conductive layer comprises a metal silicide.

10. The semiconductor device of claim 8, wherein said semiconductor substrate is an FDSOI substrate.

11. The semiconductor device of claim 8, further comprising:
another sidewall spacer formed at another sidewall of said gate electrode layer covering only a third portion and exposing a fourth portion of said other sidewall;
another raised source/drain region adjacent to said other sidewall spacer and formed over said semiconductor substrate; and
wherein said electrically conductive layer is continuously formed partly on said exposed fourth portion of said other sidewall of said gate electrode and said other raised source/drain region.

12. An SRAM cell comprising a semiconductor device according to claim 8.

13. A method of manufacturing a semiconductor device, comprising:
forming a gate electrode layer over a semiconductor substrate;
forming a sidewall spacer at a sidewall of said gate electrode layer such that it covers a first portion of said sidewall and exposes a second portion of said sidewall;
forming a raised source/drain region over said semiconductor substrate and adjacent to said sidewall spacer; and
performing a silicidation process to obtain a silicided portion of said gate electrode layer, a silicided portion of said source/drain region and a silicided layer connecting said silicided portion of said gate electrode layer and said silicided portion of said source/drain region.

14. The method of claim 13, wherein performing said silicidation process comprises forming a metal layer over said gate electrode layer including said exposed second portion of said gate electrode layer and said source/drain region and performing an anneal treatment of said metal layer.

15. The method of claim 13, wherein forming said gate electrode layer comprises forming a metal gate and a polysilicon layer above said metal gate.

16. The method of claim 13, further comprising forming a high-k gate dielectric between said gate electrode layer and said semiconductor substrate.

17. The method of claim 13, further comprising forming an additional sidewall space at another sidewall of said gate electrode, forming another source/drain region and removing a portion of said other sidewall spacer, thereby exposing a portion of said other sidewall of said gate electrode layer and wherein said silicided layer is formed to electrically contact said other source/drain region and said exposed portion of said other sidewall of said gate electrode layer.

18. The method of claim 13, wherein said semiconductor substrate is an FDSOI substrate and further comprising forming a high-k gate dielectric between said gate electrode layer and a semiconductor layer of said FDSOI substrate that is formed on a buried oxide layer of said FDSOI substrate.
